(19) United States
(12) Patent Application Publication
(10) Pub. No.: US 2026/0182275 A1
(43) Pub. Date: Jun. 25, 2026

(54) SUBSTRATE PROCESSING APPARATUS AND SUBSTRATE PROCESSING METHOD

(71) Applicant: Tokyo Electron Limited, Tokyo (JP)

(72) Inventors: Yuzo OHISHI, Kumamoto (JP); Shingo TAKAMI, Kumamoto (JP)

(21) Appl. No.: 19/422,931

(22) Filed: Dec. 17, 2025

(30) Foreign Application Priority Data
Dec. 19, 2024 (JP) 2024-224394

(51) Int. Cl. H10P 34/00; H10P 72/00

(52) U.S. Cl. CPC H10P 34/00; H10P 72/0402

(57) ABSTRACT

A substrate processing apparatus includes: a substrate holder that holds a substrate in a processing chamber; a light irradiation unit including a light source, a housing that accommodates the light source and forms a light source chamber partitioned from the processing chamber, and a window that forms a portion of the housing and transmits the light emitted from the light source to supply the light to a back surface of the substrate in the processing chamber, thereby performing a processing; a processing chamber-side gas supply that supplies an inert gas to the processing chamber; a processing chamber-side exhaust that exhausts the inert gas from the processing chamber; a light source chamber-side gas supply that supplies the inert gas to the light source chamber; and a light source chamber-side exhaust that exhausts the inert gas from the light source chamber.

### CROSS REFERENCES TO RELATED APPLICATIONS

This application is based on and claims priority from Japanese Patent Application No. 2024-224394, filed on December 19, 2024, with the Japan Patent Office, the disclosure of which is incorporated herein in its entirety by reference.

### TECHNICAL FIELD

The present disclosure relates to a substrate processing apparatus and a substrate processing method.

### BACKGROUND

In the process of manufacturing semiconductor devices, light such as ultraviolet rays may be irradiated onto the back surface of a semiconductor wafer (hereinafter, referred to as a wafer) disposed inside a substrate processing apparatus. Japanese Patent Laid-Open Publication No. 2019-121683 discloses forming a friction reducing film on the back surface of the wafer to reduce friction against an exposure stage on which the wafer is placed, and then, irradiating ultraviolet rays to remove the friction reducing film.

### SUMMARY

According to the present disclosure, a substrate processing apparatus includes: a substrate holder that holds a substrate in a processing chamber; a light irradiator including a light source, a housing that accommodates the light source and makes up a light source chamber partitioned from the processing chamber, and a window that makes up a portion of the housing and transmits light emitted from the light source to supply the light to a back surface of the substrate in the processing chamber, thereby performing a processing; a processing chamber-side gas supply that supplies an inert gas to the processing chamber; a processing chamber-side exhaust that exhausts the inert gas from the processing chamber; a light source chamber-side gas supply that supplies the inert gas to the light source chamber; and a light source chamber-side exhaust that exhausts the inert gas from the light source chamber.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal sectional side view of a substrate processing apparatus according to a first embodiment of the present disclosure.

FIG. 2 is a transverse sectional plan view of the substrate processing apparatus.

FIG. 3 is a transverse sectional plan view of the substrate processing apparatus.

FIG. 4 is a schematic side view of the substrate processing apparatus.

FIG. 5 is a schematic side view of a system including the substrate processing apparatus.

FIG. 6 is a chart view illustrating a process operation of the substrate processing apparatus.

FIG. 7 is a side view illustrating the process operation of the substrate processing apparatus.

FIG. 8 is a side view illustrating the process operation of the substrate processing apparatus.

FIG. 9 is a view illustrating a gas supply and exhaust state of the system.

FIG. 10 is a sectional view illustrating an exhaust path of the substrate processing apparatus.

FIG. 11 is a longitudinal sectional side view of the substrate processing apparatus.

FIG. 12 is a longitudinal sectional side view of a substrate processing apparatus according to a modification of the first embodiment.

FIG. 13 is a longitudinal sectional side view of a substrate processing apparatus according to a second embodiment of the present disclosure.

FIG. 14 is a transverse sectional plan view of the substrate processing apparatus.

FIG. 15 is a schematic side view of a substrate processing apparatus according to a third embodiment of the present disclosure.

FIG. 16 is a schematic view illustrating a substrate processing apparatus according to a fourth embodiment of the present disclosure.

FIG. 17 is a longitudinal sectional side view of a substrate processing apparatus according to another modification of the first embodiment.

FIG. 18 is a longitudinal sectional front view of the substrate processing apparatus according to the modification above.

FIG. 19 is a longitudinal sectional side view of a light irradiation unit of the substrate processing apparatus.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

### <First Embodiment>

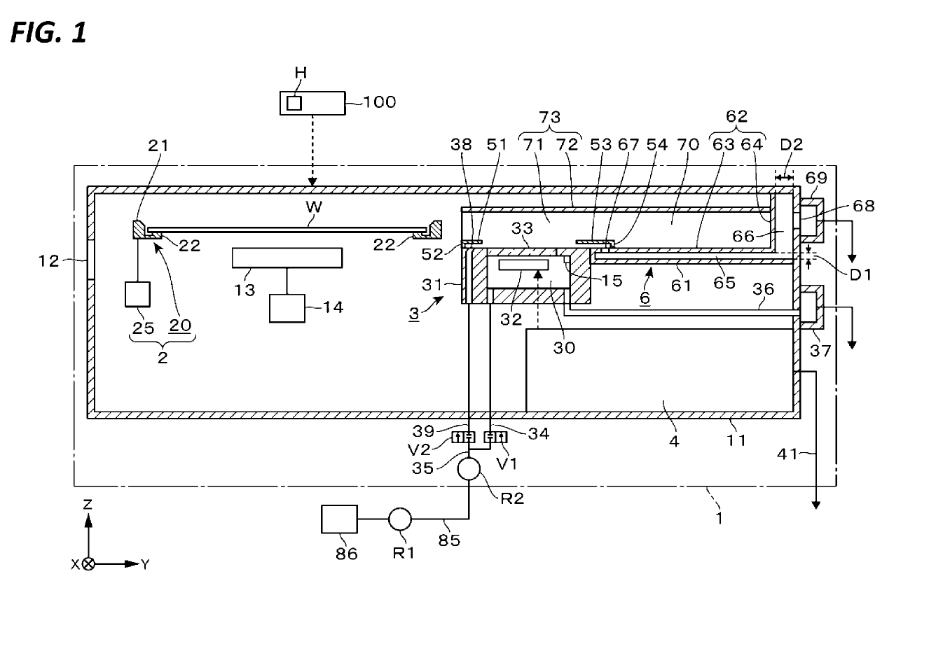

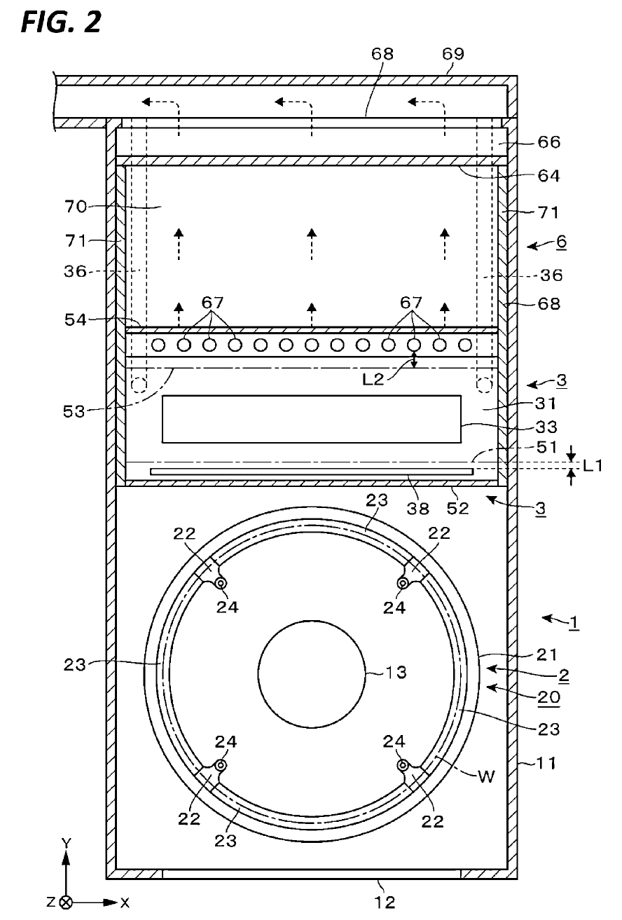

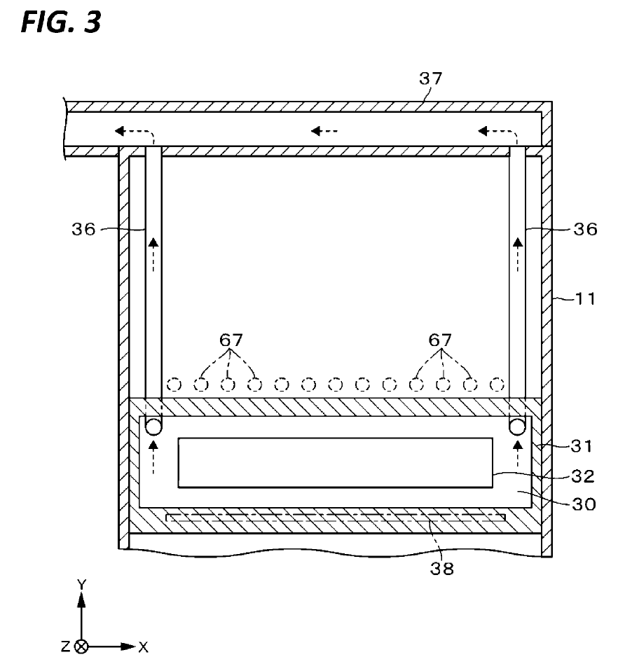

A substrate processing apparatus 1 according to a first embodiment of the present disclosure will be described with reference to the longitudinal sectional side view of FIG. 1 and the transverse sectional plan views of FIGS. 2 and 3. FIG. 3 illustrates a cross section taken at a height different from that of FIG. 2. The substrate processing apparatus 1 is provided in the air atmosphere, and performs a processing on a wafer W, which is a circular substrate. A resist film with a predetermined pattern is formed on, for example, the front surface of the wafer W, and a film of organic material (organic film) is formed on, for example, the back surface of the wafer W. A specific example of the organic material is HMDS (hexamethyldisilazane), and is a film formed for the purpose of forming the pattern in the resist film. The substrate processing apparatus 1 performs a processing of irradiating light from below to the entire back surface of the wafer W to remove the organic film. The light includes ultraviolet rays with a wavelength of 10 nm to 200 nm (e.g., vacuum ultraviolet rays), and more specifically, ultraviolet rays with a peak wavelength of, for example, 172 nm are irradiated.

However, the light described above activates oxygen in the air, generating O₃ (ozone) gas on the side of the back surface of the wafer W. Since the O₃ gas attenuates the light, there is a concern that the film removal performance may not be sufficiently achieved when the concentration of the O₃ gas becomes relatively high between the light source (ultraviolet ray irradiation source) and the wafer W. Further, in an event that the O₃ gas flows around onto the front surface of the wafer W, the resist film may be damaged and removed by the O₃ gas. As described in detail later, the substrate processing apparatus 1 is configured to prevent the problems by performing supply and exhaust of an inert gas. The dashed arrows in FIGS. 2 and 3 indicate the exhaust flow.

Hereinafter, the configuration of the substrate processing apparatus 1 will be described in detail. The substrate processing apparatus 1 includes a housing 11 that forms the outline of the apparatus, and the housing 11 has a transversely elongated rectangular shape. Descriptions will be made, defining the longitudinal direction of the housing 11 as the front-rear direction. Accordingly, the left-right direction corresponds to the width direction of the substrate processing apparatus 1. In the drawings, the X direction represents the left-right horizontal direction, the Y direction represents the front-rear horizontal direction, and the Z direction represents the vertical direction. A transfer port 12 for the wafer W is formed in the front side wall of the housing 11. A stage 13, a movement unit 2, a light irradiation unit 3, and a power supply unit 4 are provided inside the housing 11. The light irradiation unit 3 irradiates the wafer W with the light including the ultraviolet rays described above, and the movement unit 2 holds and moves the wafer W for the irradiation of light.

The stage 13 is provided in front of the light irradiation unit 3 inside the housing 11, and adsorbs the central portion of the back surface of the wafer W thereby supporting the wafer W horizontally. A transfer mechanism 81 (not illustrated in FIGS. 1 to 3) transfers the wafer W to/from the stage 13. The stage 13 is connected to a rotation mechanism 14. By the rotation mechanism 14, the stage 13 rotates together with the adsorbed wafer W around a vertical rotation axis, to change the orientation of the wafer W inside the housing 11. Changing the orientation of the wafer W is performed to change the position of the back surface of the wafer W that is held by the movement unit 2, during the processing on the entire back surface of the wafer W.

The movement unit 2 includes: a main body 21 that has an annular shape surrounding the lateral periphery of the wafer W, a substrate holder 22 that protrudes from the main body 21 toward the region surrounded by the main body 21, a movement member 20 including light shielding plates 23, and a movement mechanism 25 connected to the movement member 20. A plurality of substrate holding units 22, for example, four substrate holders 22, are provided to be spaced apart from each other in the circumferential direction of the main body 21, and adsorb and hold the peripheral edge of the back surface of the wafer W by suction from suction holes 24.

An ejection port (not illustrated) for an inert gas is formed in the inner peripheral side surface of the main body 21, to supply the inert gas into the gap formed between the lateral surface of the wafer W held by the substrate holders 22 and the side surface of the main body 21, thereby suppressing the O₃ gas from flowing around onto the front surface of the wafer W. In plan view, each light shielding plate 23 is formed in an arc shape along the circumferential direction of the main body 21, and is provided to connect the base ends of the substrate holders 22 to each other. The light shielding plates 23 prevent the light irradiated from below as described above from being supplied to the side of the front surface of the wafer W due to diffraction.

The movement mechanism 25 may move the movement member 20 upward and downward vertically and forward and backward horizontally. By the upward and downward movement of the movement member 20, the wafer W may be transferred between the stage 13 and the substrate holders 22 of the movement member 20. Further, by the forward and backward movement of the movement member 20, the wafer W is carried into a processing chamber 70, which will be described herein later, together with the movement member 20, and moves on the light irradiation unit 3 so that the light irradiation position on the back surface of the wafer W changes. That is, the light is irradiated to different locations in the front-rear direction on the back surface of the wafer W, so that the processing is performed.

The light irradiation unit 3 includes a housing 31 and a light source 32. The housing 31 has a rectangular shape, which is elongated in the left-right direction, and is provided across the width direction inside the housing 11 of the apparatus. The upper wall of the housing 31 is formed horizontally, and a portion of the upper wall is formed as a window 33 that transmits upward the light irradiated from the light source 32. Thus, a portion of the housing 31 is configured as the window 33. The window 33 is made of, for example, quartz, and its width in the left-right direction is greater than the diameter of the wafer W such that the light may be irradiated onto the entire diameter of the wafer W. The space inside the housing 31 is configured as a light source chamber 30. In the light source chamber 30, the light source 32 is disposed below the window 33 while being spaced apart from the window 33, and irradiates the light having the wavelength described above upward.

The power supply unit 4 connected to the light irradiation unit 3 will be described. The light source 32 may perform the light irradiation as described above by being powered from the power supply unit 4 provided below the light irradiation unit 3. The upstream end of an exhaust pipe 41 is connected to the power supply unit 4, and the downstream end of the exhaust pipe 41 is connected to an exhaust source (not illustrated). Through the exhaust by the exhaust source, the inside of the exhaust pipe 41 and the inside of the power supply unit 4 have a negative pressure relative to the surroundings of the power supply unit 4, and thus, the air around the power supply unit 4 is introduced into the power supply unit 4 through the exhaust pipe 41 and exhausted from the exhaust pipe 41, so that devices installed inside the power supply unit 4 are cooled. The exhaust source that exhausts the power supply unit 4 as described above, and another exhaust source to be described herein later are, for example, exhaust paths provided in a plant where a wafer processing system 8 including the substrate processing apparatus 1 (to be described herein later) is installed. The exhaust sources have a lower pressure than the atmospheric pressure, and a flow path connected to each exhaust source is exhausted.

Descriptions will be continued on the light irradiation unit 3. The downstream end of a gas supply pipe 34 is connected to the housing 31, and opens into the light source chamber 30. A valve V1 is interposed in the gas supply pipe 34, and the upstream end of the gas supply pipe 34 is connected to the downstream end of a gas supply pipe 35 in which a regulator R2 serving as a pressure regulation unit is interposed. An inert gas is supplied to the gas supply pipe 35, and the regulator R2 regulates the flow rate of the inert gas supplied to the downstream side of the gas supply pipe 35 such that the pressure of the downstream side inside the gas supply pipe 35 becomes constant. As described herein later, a regulator R1 is provided as a first regulator on the upstream side of the regulator R2, and the regulator R2 is a secondary regulator.

The upstream ends of two exhaust pipes 36 are connected to the housing 31 of the light irradiation unit 3, and the exhaust pipes 36 open into the left end portion and the right end portion of the light source chamber 30, respectively. The downstream side of each exhaust pipe 36 extends rearward inside the housing 11 of the apparatus, and the downstream end of each exhaust pipe 36 is connected to the rear side wall of the housing 11. A duct 37 is formed to be connected to the rear side wall of the housing 31 from the outside of the housing 31 and extend horizontally to the left-right direction, and the downstream end of each exhaust pipe 36 opens into the flow path inside the duct 37. The duct 37 is connected to an exhaust source 80 (not illustrated in FIGS. 1 to 3), and the inside of the duct 37 is exhausted by the exhaust source 80.

With the configuration above, the inert gas may be supplied into the light source chamber 30 when the valve V1 is opened, and the light source chamber 30 may be exhausted by the exhaust source through the duct 37 and the exhaust pipes 36 at all times. During the supply of the inert gas, the inert gas is exhausted into the duct 37, and when the inert gas is not supplied, the air introduced into the light source chamber 30 from the outside of the housing 31 is exhausted into the duct 37. The supply of the inert gas into the light source chamber 30 is performed during the light irradiation from the light source 32. In this way, the gas supply and exhaust in the light source chamber 30 during the light irradiation are performed to prevent the light emitted from the light source 32 from being significantly attenuated due to an increase in concentration of the O₃ gas generated during the light irradiation between the window 33 and the light source 32. Another purpose for the gas supply and exhaust is to prevent defects resulting from oxidation of metal components inside the light source chamber 30 that may occur due to the O₃ gas.

As described above, a plurality of exhaust channels (two exhaust channels in the present example) is formed by the exhaust pipes 36, respectively, to extend from the light source chamber 30 while being separated in the left-right direction. Three or more exhaust pipes 36 may be arranged in the left-right direction, such that the light source chamber 30 is connected to the duct 37 at three or more locations thereof. The exhaust pipes 36 and the duct 37 make up a light source chamber-side exhaust unit. The valve V1 and the gas supply pipe 34 make up a light source chamber-side gas supply unit.

A pressure sensor 15 is provided in the light source chamber 30, and a control device 100 to be described herein later may detect the pressure of the light source chamber 30 based on a detection signal output from the pressure sensor 15. When the pressure deviates from an allowable range during the opening of the valve V1, the control device 100 determines that an abnormality occurs, outputs a control signal, closes the valve V1, and terminates, for example, the processing on the wafer W. The supply of the inert gas is stopped by the closing of the valve V1, so that an occurrence of problems, such as damage to the window 33 caused by excessive pressurization, is prevented.

In the upper surface of the housing 31 of the light irradiation unit 3, a gas ejection port 38 is formed in front of the window 33. The gas ejection port 38 is opened obliquely upwardly toward the rear side, and is formed, for example, in a slit shape extending in the left-right direction. The downstream end of a gas supply pipe 39 with a valve V2 interposed therein is connected to the housing 31, and the downstream end of the gas supply pipe 39 communicates with the gas ejection port 38 through a flow path formed in the housing 31.

The upstream end of the gas supply pipe 39 is connected to the downstream end of the gas supply pipe 35. Accordingly, the downstream of the gas supply pipe 35 with the regulator R2 interposed therein branches to form the gas supply pipes 34 and 39, and the regulator R2 is shared by the gas supply pipes 34 and 39. By opening the valve V2, the inert gas is ejected from the gas ejection port 38. The gas ejection port 38, the valve V2, and the portion of the gas supply pipe 39 on the downstream side relative to the valve V2 make up a processing chamber-side gas supply unit.

An airflow direction regulation plate 51 is provided as a first regulation member above the gas ejection port 38 while forming a gap from the gas ejection port 38. The airflow direction regulation plate 51 is horizontally supported by a support unit 52 provided in front of the gas ejection port 38. Since the airflow direction regulation plate 51 is disposed on the extension line of the gas ejection from the gas ejection port 38, the inert gas ejected from the gas ejection port 38 collides with the airflow direction regulation plate 51. Then, the inert gas flows horizontally along the lower surface of the airflow direction regulation plate 51 and moves rearward.

An exhaust path formation unit 6 is formed behind the light irradiation unit 3, to form an exhaust path for the inert gas ejected from the gas ejection port 38. The exhaust path formation unit 6 includes a lower plate 61 and an upper plate 62 disposed above the lower plate 61. The lower plate 61 is configured as a horizontal plate that vertically partitions the region behind the light irradiation unit 3 inside the housing 11, and the upper plate 62 is configured as a plate with a rear portion thereof bent at 90° with respect to a front portion. The front portion of the upper plate 62 makes up a horizontal portion 63 that vertically partitions the region behind the light irradiation unit 3 and is disposed to face the lower plate 61 with a relatively small gap from the lower plate 61. The rear portion of the upper plate 62 makes up a vertical portion 64 that is disposed to face the rear side wall of the housing 11, thereby partitioning the region above the lower plate 61 inside the housing 11 in the left-right direction.

The region surrounded by the lower plate 61, the upper plate 62, and the housing 11 serves as an exhaust path partitioned from the surroundings, and the gas flows rearward in the exhaust path, which will be described herein later. The exhaust path has an L shape when viewed in the left-right direction, and includes a transverse exhaust path 65 that is formed by the horizontal portion 63 of the upper plate 62 to extend horizontally from the front side to the rear side, and a vertical exhaust path 66 that is connected to the downstream end of the transverse exhaust path 65 and is formed by the side wall of the housing 11 to extend vertically upward.

Each of the transverse exhaust path 65 and the vertical exhaust path 66 is formed in a rectangular shape when viewed from each of the left-right direction, the front-rear direction, and the up-down direction, and for example, the width of the transverse exhaust path 65 in the left-right direction is equal to the width of the vertical exhaust path 66 in the left-right direction. The height D1 of the transverse exhaust path 65 is smaller than the length D2 of the vertical exhaust path 66 in the front-rear direction (see, e.g., FIG. 1). Thus, since the cross-sectional area of the transverse exhaust path 65 in the flow path direction is larger than that of the vertical exhaust path 66, the pressure loss by the gas (air and inert gas) flowing through the transverse exhaust path 65 is greater than that in the vertical exhaust path 66. Further, since the length D2 of the vertical exhaust path 66 in the front-rear direction is shorter than the length of the transverse exhaust path 65 in the front-rear direction, and the width of the vertical exhaust path 66 in the left-right direction is greater than the length D2 of the vertical exhaust path 66 in the front-rear direction, the vertical exhaust path 66 is formed in a strip shape extending in the left-right direction in plan view.

The upper surface of the upper plate 62 is provided to be continuous with the upper surface of the housing 31 of the light irradiation unit 3. That is, the upper surface of the upper plate 62 and the upper surface of the housing 31 are in contact and flush with each other. A plurality of exhaust ports 67 is formed at the front side of the upper plate 62 to be each directed toward the vertical direction, and opens into the transverse exhaust path 65. The plurality of exhaust ports 67 are arranged in a row along the left-right direction while being spaced apart from each other.

An opening 68 is formed in the rear side wall of the housing 11 to extend in the left-right direction, and opens into the vertical exhaust path 66. A duct 69 is provided to be connected to the rear side wall of the housing 11 from the outside of the housing 11. The duct 69 is located above the duct 37, and extends horizontally in the left-right direction. Similarly to the duct 37, the duct 69 is also connected to an exhaust source 80, so that the inside thereof is exhausted. The opening 68 described above also opens into the duct 69. Thus, the inert gas ejected from the gas ejection port 38 flows and is exhausted through the exhaust ports 67, the transverse exhaust path 65, the vertical exhaust path 66, and the duct 69 in this order.

At both the left end and the right end inside the housing 11 of the apparatus, support units 71 are provided to extend from the front end on the housing 31 of the light irradiation unit 3 toward the rear end of the horizontal portion 63 of the exhaust path formation unit 6, while protruding upward. The support units 71, together with a horizontal plate 72 supported by the support units 71, make up a cavity formation member 73, and the cavity surrounded by the cavity formation member 73 is configured as a processing chamber 70 into which the wafer W supported by the movement member 20 is carried to be subjected to the light irradiation. Accordingly, the processing chamber 70 is a space formed above the light source chamber 30, and is partitioned from the light source chamber 30. The movement member 20 transfers the wafer W into the processing chamber 70, so that the processing is performed. Since the processing chamber 70 is formed as described above, the gas ejection port 38 ejects the inert gas into the processing chamber 70, and the exhaust ports 67 exhaust the processing chamber 70. Then, air may be introduced into the processing chamber 70 from the front side.

The exhaust from the exhaust ports 67 through the duct 69 is performed at all times. The flow path of each unit of the substrate processing apparatus 1 is formed between the processing chamber 70 and the light source chamber 30 to increase the exhaust amount of the processing chamber 70, and the air of the processing chamber 70 is also exhausted from the exhaust ports 67 when the inert gas is or is not supplied from the gas ejection port 38. The exhaust path formation unit 6 and the duct 69 described above make up a processing chamber-side exhaust unit.

An airflow direction regulation plate 53 is provided above the exhaust ports 67 with a gap from the exhaust ports 67, to serve as a second regulation member. The airflow direction regulation plate 53 is horizontally supported by a support unit 54 provided on the rear side of the exhaust ports 67. The airflow direction regulation plate 53, the exhaust ports 67, and the above-described airflow direction regulation plate 51 and gas ejection port 38 will be described in more detail. During the processing of the wafer W, the light is irradiated onto the back surface of the wafer W positioned above the window 33, through the window 33. As described above, the light irradiation causes the generation of O₃ gas from the air, and when the concentration of O₃ gas becomes high, the performance of removing the film on the back surface of the wafer W degrades.

In order to prevent the problem above, during the light irradiation, the inert gas is ejected from the gas ejection port 38, and the O₃ gas is purged toward the exhaust ports 67. The airflow direction regulation plate 51 regulates the flow of the inert gas to be directed rearward, thereby preventing the inert gas, together with the O₃ gas, from flowing toward the wafer W.

As described above, since the exhaust from the exhaust ports 67 is performed at all times, suction is performed from the exhaust ports 67 even when the O₃ gas is purged by the inert gas, so that the purged O₃ gas is introduced into the exhaust ports 67 and is removed. When the exhaust ports 67 exhaust the surroundings of the wafer W during the removal of the O₃ gas, the generated O₃ gas may easily flow toward the wafer W. That is, the exhaust flow of the O₃ gas may be formed to pass through the surroundings of the wafer W, and consequently, the resist film on the front surface of the wafer W may be removed.

Thus, by providing the airflow direction regulation plate 53, the direction of the exhaust by the exhaust ports 67 may be prevented from being directed upward, and the front side of the exhaust ports 67 may be exhausted. That is, the O₃ gas flowing rearward by the inert gas is sucked together with the inert gas to flow toward the front side of the exhaust ports 67 and be introduced into the exhaust ports 67, so that the O₃ gas and the inert gas are prevented from being supplied upward into the processing chamber 70. In the present example, the airflow direction regulation plate 53 has a relatively longer length in the front-rear direction to more reliably achieve the operation of the airflow direction regulation plate 53. As illustrated in FIG. 2, the length L2 from the front end of the exhaust ports 67 to the front end of the airflow direction regulation plate 53 is greater than the length L1 from the rear end of the gas ejection port 38 to the rear end of the airflow direction regulation plate 51.

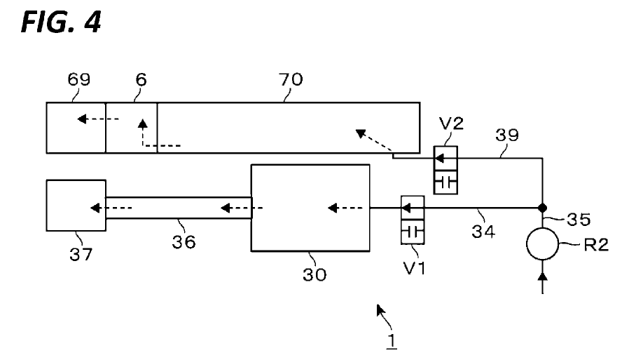

FIG. 4 is a schematic configuration view of the substrate processing apparatus 1 described above, and represents the flow of the inert gas supplied from the gas supply source using dashed arrows. The supply channel of the inert gas is divided into the supply channel from the downstream side of the regulator R2 toward the processing chamber 70, and the supply channel toward the light source chamber 30. The exhaust channel from the processing chamber 70 is formed as the exhaust path by the exhaust path formation unit 6 and the duct 69, and separately, the exhaust channel from the light source chamber 30 is formed as the exhaust pipes 36 and the duct 37. Hereinafter, the ducts 37 and 69 may be referred to as the light source chamber-side exhaust duct 37 and the processing chamber-side exhaust duct 69, respectively, to discriminate the ducts.

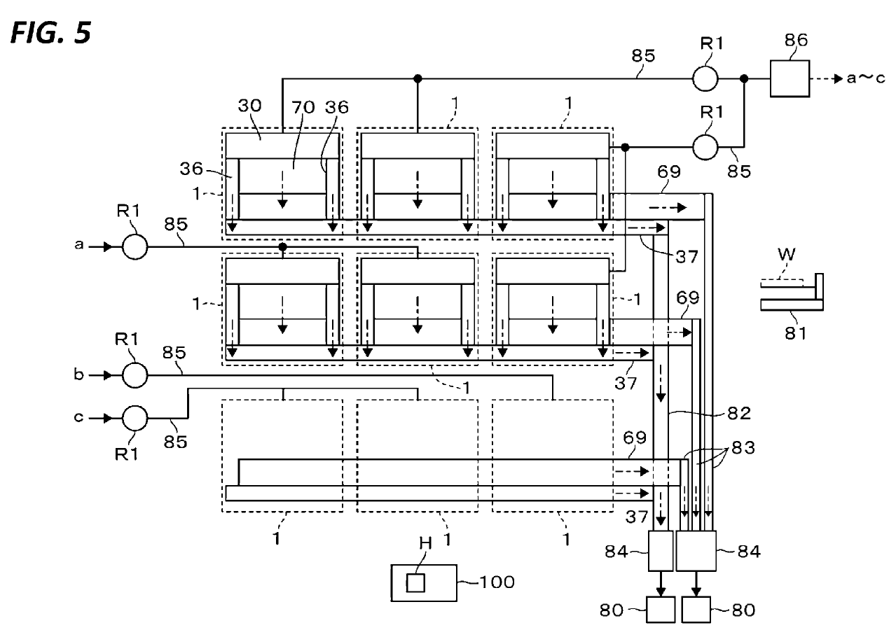

Next, an example of a wafer processing system 8 including a plurality of substrate processing apparatuses 1 will be described with reference to the schematic side view of FIG. 5. In the wafer processing system 8, the substrate processing apparatuses 1 are arranged in multiple vertical stages, and the substrate processing apparatuses 1 in each stage are arranged in a row along the left-right direction (e.g., X direction). In the example illustrated in FIG. 5, the substrate processing apparatuses 1 are arranged in three stages, and three substrate processing apparatuses 1 are arranged in each stage, so that a total of nine substrate processing apparatuses 1 are provided in the wafer processing system 8. When viewed from the side, the substrate processing apparatuses 1 are arranged in a 3×3 matrix.

The wafer processing system 8 includes a transfer mechanism (e.g., a transfer device) 81. The transfer mechanism 81 transfers a wafer W between a transfer container accommodating the wafer W such as a FOUP (Front Opening Unified Pod), and a substrate processing apparatus 1 of a transfer destination, and the processing of the wafer W is performed in the substrate processing apparatus 1 of the transfer destination. While FIG. 5 illustrates one transfer mechanism 81 shared among the substrate processing apparatuses 1 arranged in the three stages, the number of substrate processing apparatuses 1 to which the wafer W is delivered by a single transfer mechanism 81, and the number of transfer mechanisms 81 are arbitrary. For example, the transfer mechanism 81 may be provided for each stage, such that the same transfer mechanism 81 may transfer the wafer W to the three substrate processing apparatuses 1 arranged in the same stage.

Each of the light source chamber-side exhaust duct 37 and the processing chamber-side exhaust duct 69 is shared among the three substrate processing apparatuses 1 arranged in the same stage. For example, as described above, the ducts 37 and 69 are provided to extend horizontally in the left-right direction. The housings 11 of the three substrate processing apparatuses 1 are connected to the ducts 37 and 69 at different positions in the longitudinal direction of the ducts (e.g., the left-right direction), respectively. Thus, in the wafer processing system 8, the light source chamber-side exhaust ducts 37 and the processing chamber-side exhaust ducts 69 are provided vertically in three stages.

One end of each of the light source chamber-side exhaust ducts 37 and the processing chamber-side exhaust ducts 69 in the left-right direction is closed. The other end of each light source chamber-side exhaust duct 37 in the left-right direction (e.g., the right end in FIG. 5) is connected to a vertical duct 82 extending downward, and the other end of each processing chamber-side exhaust duct 69 in the left-right direction (e.g., the right end in FIG. 5) is connected to a vertical duct 83 extending downward. The lower ends of the vertical ducts 82 and 83 are connected to the exhaust sources 80, respectively, and exhaust is performed by the exhaust sources 80. Thus, through the vertical ducts 82 and 83, the inside of each light source chamber-side exhaust duct 37 and the inside of each processing chamber-side exhaust duct 69 are exhausted from the other ends of the ducts in the left-right direction. While FIG. 5 illustrates the exhaust source 80 to which the vertical duct 82 is connected, and the exhaust source 80 to which the vertical duct 83 is connected, as separate components, a common exhaust source may be provided. In FIG. 5, the reference numeral 84 refers to a O₃ gas removal filter interposed in each of the vertical ducts 82 and 83.

The wafer processing system 8 further includes a plurality of gas supply pipes 85 each provided with a regulator R1 interposed therein, and the inert gas is supplied from an inert gas supply source 86 to the gas supply pipes 85. The inert gas supplied from the inert gas supply source 86 is, for example, N₂ (nitrogen) gas. Each regulator R1 regulates the flow rate of the inert gas supplied to the downstream side of the corresponding gas supply pipe 85, such that the pressure inside the gas supply pipe 85 on the downstream side of the regulator R1 becomes constant.

Each gas supply pipe 85 branches at the downstream side thereof relative to the position of the regulator R1, and is connected to the regulator R2 provided in each of two substrate processing apparatuses 1 that are adjacent to each other in the left-right direction or the up-down direction (see, e.g., FIG. 1). In this way, the regulator R1 is shared by two substrate processing apparatuses 1. However, since the number of substrate processing apparatuses 1 provided in the wafer processing system 8 is nine, one of the substrate processing apparatuses 1 does not share the regulator R1 with the other substrate processing apparatus 1.

In the wafer processing system 8 described above, a control device 100 is provided to serve as a control unit. The control device 100 is, for example, a computer, and includes a program storage unit (not illustrated). The program storage unit stores a program for controlling the processing of the wafer W in the wafer processing system 8. The program storage unit further stores a program for controlling the operation of the drive system including, for example, the various processing apparatuses and the transfer device that have been described, to implement the wafer processing in the wafer processing system 8. The programs include a series of steps required to perform the transfer and the processing of the wafer W in the wafer processing system 8, and according to the programs, the control device 100 outputs control signals to the respective components of the wafer processing system 8, to control the components thereby executing the transfer and the processing as described above. Further, the control device 100 determines whether the abnormality described above occurs, and when it is determined that the abnormality occurs, outputs an alarm by sound or on-screen display to notify the abnormality.

The programs described above may be recorded on a computer-readable storage medium H, and may be installed into the control device 100 from the storage medium H. The storage medium H may include a ROM, a RAM, or a hard disk, but its structure or type is not limited and may be temporary or non-temporary. The control device 100 may include units that perform storage, reading, and execution of the programs for implementing the wafer processing, and related communications, and the units may be located inside or outside the wafer processing system 8. The control device 100 may be a single circuit or a plurality of circuits, and may be provided in an integrated form or in a partially divided form. The control device 100 controls the operation of the substrate processing apparatus 1, and may be regarded as being provided in the substrate processing apparatus 1.

Since the wafer processing system 8 is configured as described above, the gas supply system (e.g., the inert gas supply source 86, the gas supply pipes 85, and the regulators R1) is shared among the plurality of substrate processing apparatuses 1, and each of the light source chamber-side exhaust ducts 37 and the processing chamber-side exhaust ducts 69 that make up an exhaust system is also shared. That is, the plurality of substrate processing apparatuses 1 are connected to each other via each of the gas supply system and the exhaust system, and the inert gas supply pressure from the gas supply system and the exhaust pressure from the plant are applied to each substrate processing apparatus 1.

Thus, when the processing of the wafer W starts or is stopped in one substrate processing apparatus 1, or the supply of the inert gas into the light source chamber 30 is stopped due to the determined abnormality, the balance between the inert gas supply pressure and the exhaust pressure fluctuates, which may affect the gas supply and exhaust in the other substrate processing apparatuses 1. When the influence is significant, in the other substrate processing apparatuses, the flow rate of the gas (e.g., air and inert gas) of the processing chamber 70 may change significantly, causing an abnormality in the processing of the wafer W, or the flow rate of the inert gas in the light source chamber 30 may change significantly, causing the deviation of the pressure in the light source chamber 30 from the allowable range, which may be determined to be abnormal. However, the wafer processing system 8 described above is configured to prevent the problems.

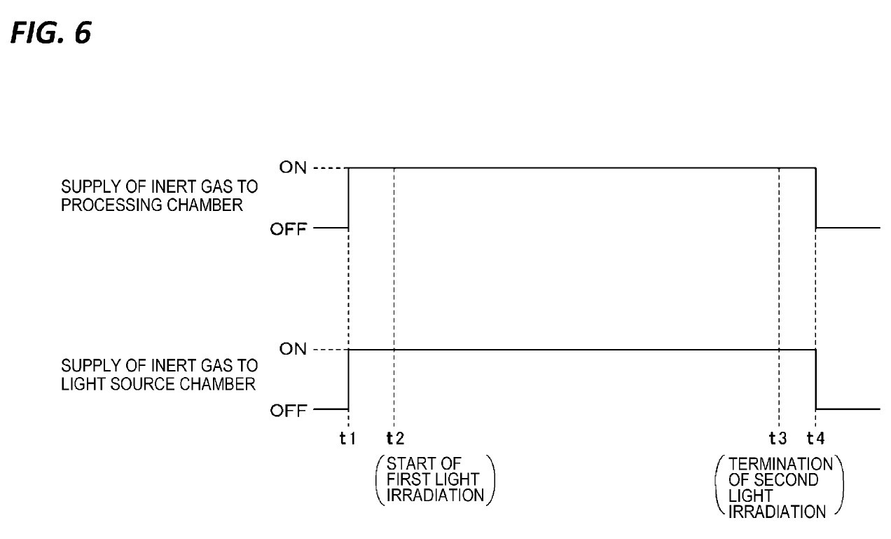

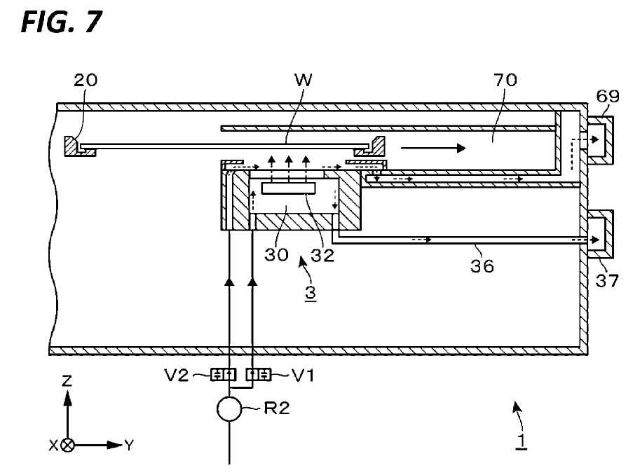

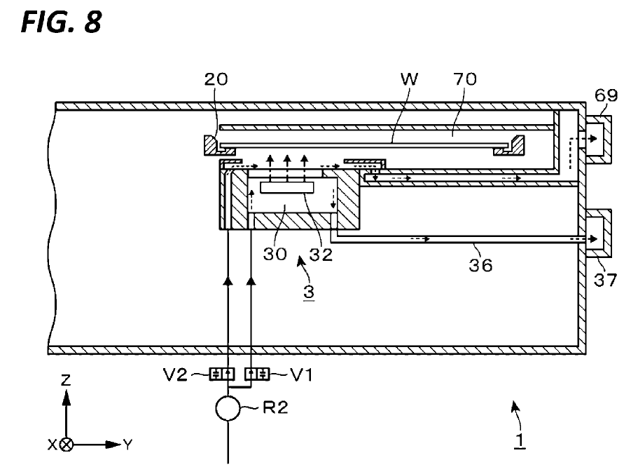

In order to describe the prevention of the problems above, the operation performed in each substrate processing apparatus 1 to process the wafer W will be described with reference to the timing chart of FIG. 6 and the side views of FIGS. 7 and 8 illustrating the operation of the substrate processing apparatus 1. The timing chart of FIG. 6 represents time periods for supplying the inert gas to the processing chamber 70 and the light source chamber 30, and thus, represents timings for opening and closing the valves V1 and V2. In FIGS. 7 and 8, dashed arrows indicate the gas flow direction, and long and short dashed arrows indicate the direction of light irradiation from the light source 32.

When the transfer mechanism 81 places the wafer W on the stage 13 in the state where the valves V1 and V2 are closed such that the air flows at a specific exhaust flow rate from the processing chamber 70 to the duct 69 and also from the light source chamber 30 to the duct 37, the movement member 20 that has waited below the stage 13 moves up to receive and hold the wafer W. FIG. 1 illustrates the state where the movement member 20 holds the wafer W. Then, both the valves V1 and V2 are opened (e.g., timing t1 in the chart), and the inert gas is supplied to the processing chamber 70 and the light source chamber 30. The gas flowing from the light source chamber 30 to the duct 37 transitions from the air to the inert gas. The gas flowing from the processing chamber 70 to the duct 69 becomes a mixed gas of the inert gas and the air, and as the flow rate of the inert gas flowing to the duct 69 increases, the flow rate of the air flowing to the duct 69 decreases accordingly. Further, the light irradiation from the light source 32 of the light irradiation unit 3 into the processing chamber 70 starts.

The movement member 20 moves rearward to carry the wafer W into the processing chamber 70. When the rear end side of the wafer W is positioned above the window 33, a first light irradiation starts as illustrated in FIG. 7 (e.g., timing t2). As the movement member 20 continues to move rearward, the light is irradiated over the region of the wafer W from the rear side to the front side as illustrated in FIG. 8. Then, when the movement member 20 moves to a predetermined position, the movement member 20 stops the rearward movement, and begins to move forward. During the forward movement as well, the light irradiation onto the wafer W is performed. When the wafer W is carried out of the processing chamber 70, the light source 32 turns off, and the first light irradiation is terminated. The movement member 20 returns to the position illustrated in FIG. 1. At this time, the supply of the inert gas to the processing chamber 70 and the light source chamber 30 is continued.

Then, after the movement member 20 moves down to deliver the wafer W to the stage 13, the stage 13 rotates 90°. Then, the movement member 20 moves up to adsorb and hold the wafer W again, and operates in the same manner as in the first light irradiation to perform a second light irradiation onto the wafer W. That is, the movement member 20 moves rearward and forward to perform the second light irradiation, and during the second light irradiation, the processing of the wafer W is performed by irradiating the light onto an unprocessed region that includes the portion overlapping with the substrate holder 22 of the movement member 20. Then, when the wafer W is carried out from the processing chamber 70 by the forward movement of the movement member 20, the light source 32 turns off, and the second light irradiation is terminated (e.g., timing t3). At this time, the light irradiation onto the entire back surface of the wafer W is completed, and the film has been removed from the entire back surface of the wafer W.

Then, both the valves V1 and V2 are closed (e.g., timing t4) to stop the supply of the inert gas to the processing chamber 70 and the light source chamber 30. The gas flowing from the light source chamber 30 to the duct 37 transitions to the air. The gas flowing from the processing chamber 70 to the duct 69 becomes solely the air, and the flow rate of the air flowing to the duct 69 increases by the amount equal to the flow rate of the inert gas of which supply has been stopped. Then, the movement member 20 moves down to deliver the wafer W to the stage 13, and the wafer W is carried out of the substrate processing apparatus 1 by the transfer mechanism 81.

The configuration of the substrate processing apparatus 1 related to the processing of the wafer W described above with reference to FIGS. 6 to 8 will be described in more detail. In the substrate processing apparatus 1, the regulator R2 is provided in the gas supply pipe 35 (see, e.g., FIG. 4) to regulate the pressure of the light source chamber 30 within the allowable range. However, in order to regulate the pressure of the light source chamber 30 within the allowable range, the regulator R2 may be provided in the gas supply pipe 34 that branches from the gas supply pipe 35 and is connected to the light source chamber 30, rather than in the gas supply pipe 35.

In the process described with reference to the chart of FIG. 6, the inert gas is continuously supplied to the processing chamber 70 during the time period from the start of the processing on the wafer W to the termination of the processing. However, during the time period when the wafer W is not placed in the processing chamber 70 such as the time period when the stage 13 changes the orientation of the wafer W, the inert gas is not supplied to the processing chamber 70, which does not affect the processing of the wafer W. From the viewpoint of suppressing the inert gas consumption to reduce operating costs of the apparatus, the supply of the inert gas to the processing chamber 70 may be stopped during the time period when the wafer W is not placed in the processing chamber 70.

However, as described in the chart of FIG. 6, in the substrate processing apparatus 1, the processing of the wafer W is performed under the condition that the time period for supplying the inert gas to the processing chamber 70 coincides with the time period for supplying the inert gas to the light source chamber 30. That is, the inert gas is supplied even when the wafer W is not placed in the processing chamber 70. In the case where the processing is performed under the condition that the time period for supplying the inert gas to the processing chamber 70 coincides with the time period for supplying the inert gas to the light source chamber 30, the regulator R2 may be provided to regulate the flow rate of the gas supplied to both the gas supply pipe 34 connected to the light source chamber 30 and the gas supply pipe 39 connected to the processing chamber 70. Therefore, the regulator R2 is not provided in the gas supply pipe 34, but is provided in the gas supply pipe 35 that is disposed on the upstream side of the gas supply pipe 34 making up the flow path toward the light source chamber 30 and the gas supply pipe 39 making up the flow path toward the processing chamber 70, and serves as the branching source of the gas supply pipes 34 and 39.

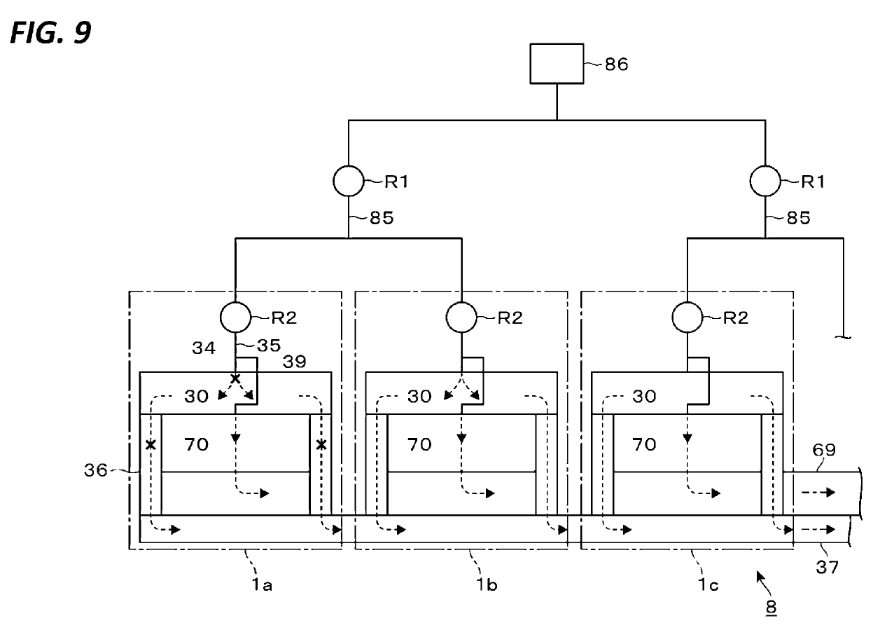

Descriptions will be continued by referring to FIG. 9 illustrating three substrate processing apparatuses 1 on the same stage in the wafer processing system 8. For the convenience in description, the three substrate processing apparatuses 1 will be denoted with 1a, 1b, and 1c in this order from the left. It may be assumed that a pressure abnormality is detected in the light source chamber 30 of the substrate processing apparatus 1a, and the valve V1 is closed to stop the supply of the inert gas to the light source chamber 30.

The substrate processing apparatus 1a shares the gas supply pipe 85 with the substrate processing apparatus 1b. When the supply of the inert gas to the light source chamber 30 of the substrate processing apparatus 1a is stopped, the pressure of the gas supply pipe 85 changes, and the flow rate of the inert gas flowing through the gas supply pipe 85 changes. However, as described above, in the substrate processing apparatus 1b, the regulator R2 is provided in the gas supply pipe 35, which is the branching source of the gas supply pipe 34 making up the flow path toward the light source chamber 30 and the gas supply pipe 39 making up the flow path toward the processing chamber 70. Therefore, fluctuation of the flow rate of the inert gas supplied to the light source chamber 30 and fluctuation of the flow rate of the inert gas supplied to the processing chamber 70 are each suppressed. Thus, in the substrate processing apparatus 1b, the pressure of the light source chamber 30 is prevented from deviating from the allowable range, and thus, being determined to be abnormal. Further, since the gas (e.g., air and inert gas) continuously flows at the stable flow rate in the processing chamber 70 of the substrate processing apparatus 1b, it is possible to prevent an occurrence of abnormality in the processing of the wafer W such as an occurrence where the flow of the O₃ gas generated during the light irradiation becomes turbulent, causing the O₃ gas to flow around onto the front surface of the wafer W.

The gas supply pipes 85 connected to the respective substrate processing apparatuses 1 are connected to each other on the upstream side relative to the position where the regulator R1 is provided. Thus, by the stop of the supply of the inert gas to the light source chamber 30 of the substrate processing apparatus 1a, the pressure of the gas supply pipe 85 connected to the substrate processing apparatus 1 other than the substrate processing apparatuses 1a and 1b (e.g., the substrate processing apparatus 1c) may also change, and the flow rate of the inert gas supplied to the downstream side may change. However, since the regulator R2 is also provided in the substrate processing apparatus 1 other than the substrate processing apparatus 1b as described above, the change in flow rate of the gas flowing through the light source chamber 30 and the processing chamber 70 is suppressed as in the substrate processing apparatus 1b.

Meanwhile, it may be assumed that by the stop of the supply of the inert gas to the light source chamber 30 of the substrate processing apparatus 1a, the flow rate of the inert gas flowing to the light source chamber-side exhaust duct 37 through the exhaust pipes 36 changes, and the pressure in the light source chamber-side exhaust duct 37 changes. However, the processing chambers 70 of the substrate processing apparatuses 1a to 1c are connected to the processing chamber-side exhaust duct 69, that is provided separately from the light source chamber-side exhaust duct 37, via the transverse exhaust path 65 and the vertical exhaust path 66. That is, the exhaust channel of the processing chambers 70 of the substrate processing apparatuses 1a to 1c and the exhaust channel of the light source chambers 30 of the substrate processing apparatuses 1a to 1c are provided separately from each other.

Thus, even when the pressure change occurs in the light source chamber-side exhaust duct 37 due to the change in amount of gas inflow, the change in flow rate of the gas flowing from the processing chamber 70 of each of the substrate processing apparatuses 1a to 1c to the processing chamber-side exhaust duct 69 is suppressed. That is, in each processing chamber 70, the inert gas and the air each continuously flow at the stable flow rate. Therefore, in each of the substrate processing apparatuses 1b and 1c, the occurrence of abnormality in the processing of the wafer W is prevented.

For the convenience in description, descriptions have been made assuming that the supply of the inert gas to the light source chamber 30 of the substrate processing apparatus 1a is stopped due to the occurrence of abnormality. However, since the processing of the wafer W is performed independently in each of the substrate processing apparatuses 1a to 1c, the supply of the inert gas to the light source chamber 30 of the substrate processing apparatus 1a may be stopped as the processing of the wafer W in the substrate processing apparatus 1a is terminated, during the processing of the wafer W in the substrate processing apparatuses 1b and 1c. Further, the pressure in each of the gas supply system and the exhaust system also changes as the processing of the wafer W starts. Thus, even when the processing of the wafer W starts or is terminated, the change in gas flow rate in the light source chambers 30 and the processing chambers 70 of the substrate processing apparatuses 1b and 1c connected to the substrate processing apparatus 1a is prevented as in when the abnormality occurs. While descriptions have been made on the case where the supply of the inert gas to the light source chamber 30 of the substrate processing apparatus 1a among the apparatuses of the substrate processing system 8 is stopped, the occurrence of abnormality in the substrate processing apparatus 1 other than the substrate processing apparatus 1a may also be prevented as described above when the supply of the inert gas to the light source chamber 30 of the corresponding substrate processing apparatus 1 is stopped.

As described above, in the substrate processing apparatus 1, the supply and exhaust of the inert gas are performed for the light source chamber 30. Thus, the attenuation of the light irradiated from the light source 32 onto the wafer W is suppressed, so that the processing of the wafer W may be stably performed. More specifically, the film may be prevented from remaining on the back surface of the wafer W due to insufficient intensity of the irradiated light.

Further, in the configuration where the respective substrate processing apparatuses 1 are connected to each other via the gas supply system and the exhaust system to make up the wafer processing system 8, the change in flow rate of the inert gas supplied to the light source chamber 30 and the processing chamber 70 is suppressed by the arrangement of the regulators R2 and the simultaneous supply of the inert gas to the light source chamber 30 and the processing chamber 70. Further, by individually providing the light source chamber-side exhaust duct 37 and the processing chamber-side exhaust duct 69 to separate the exhaust channel of the light source chamber 30 and the exhaust channel of the processing chamber 70, the change in gas flow rate in the processing chamber 70 is suppressed. Therefore, the supply of the inert gas to the light source chamber 30 is prevented from being undesirably stopped due to the change in pressure of the light source chamber 30 even though no abnormality occurs in the apparatus, and the flow of the O₃ gas in the processing chamber 70 is prevented from becoming turbulent. As a result, the processing of the wafer W may be stably performed in the substrate processing apparatus 1.

In order to exhaust the light source chamber 30 in the substrate processing apparatus 1, as illustrated in FIG. 3, the light source chamber 30 is connected to the light source chamber-side exhaust duct 37 via the two exhaust pipes (lines) 36, and the exhaust pipes 36 are connected to exhaust the light source chamber 30 at locations spaced apart from each other in the left-right direction along the width direction of the light source chamber 30. Instead of connecting the inside of the housing 31 and the light source chamber-side exhaust duct 37 using the two exhaust pipes 36, the light source chamber 30 and the light source chamber-side exhaust duct 37 may be connected using a single exhaust pipe (referred to as a virtual exhaust pipe for the convenience in description). For example, it may be assumed that the cross-sectional area of the pipe passage inside each exhaust pipe 36 is A, and the cross-sectional area of the virtual exhaust pipe is 2A. That is, the cross-sectional area of the pipe passage of the virtual exhaust pipe is equal to the total cross-sectional area of the pipe passages of the two exhaust pipes 36.

However, even though the cross-sectional area of the pipe passage of the virtual exhaust pipe and the cross-sectional area of the pipe passages of the exhaust pipes 36 have the relationship above, it is difficult for the gas to flow through the two exhaust pipes 36 each of which pipe passage has the small cross-sectional area, and therefore, the pressure loss of the gas flowing from the light source chamber 30 toward the light source chamber-side duct 37 increases relatively. Since it is advantageous that the gas flow path from the light source chamber 30 toward the light source chamber-side exhaust duct 37 has the relatively greater pressure loss, the two exhaust pipes 36 may be provided as illustrated in FIG. 3, rather than providing the virtual exhaust pipe.

Increasing the pressure loss between the light source chamber 30 and the light source chamber-side exhaust duct 37 will be described in more detail, referring back to FIG. 9 and assuming a case where the supply of the inert gas to the light source chamber 30 of the substrate processing apparatus 1a among the substrate processing apparatuses 1a to 1c is stopped. Further, it may be assumed that as the supply of the inert gas is stopped, the flow rate of the gas flowing from the light source chamber 30 into the light source chamber-side exhaust duct 37 in the substrate processing apparatus 1a changes, and the pressure in the light source chamber-side exhaust duct 37 changes.

At this time, in the substrate processing apparatuses 1b and 1c, when the flow path between the light source chamber 30 and the light source chamber-side exhaust duct 37 has the large pressure loss and the low gas flowability, the flow rate of the gas flowing through the light source chamber 30 and the pressure of the light source chamber 30 in the substrate processing apparatuses 1b and 1c are suppressed from changing in response to the pressure change in the light source chamber-side exhaust duct 37. That is, even when the pressure in the light source chamber-side exhaust duct 37 changes relatively rapidly and relatively significantly, the change in flow rate of the inert gas and the change in pressure in the light source chambers 30 of the substrate processing apparatuses 1b and 1c are relatively moderate and small. Therefore, in the substrate processing apparatuses 1b and 1c, it is possible to more reliably prevent the pressure in the light source chamber 30 from deviating from the allowable range, and thus, being determined to be abnormal even though no abnormality occurs.

Further, exhausting the light source chamber 30 from the plurality of locations through the exhaust pipes 36 is also advantageous from the viewpoint of suppressing uneven exhaust in the light source chamber 30, thereby preventing the O₃ gas from easily remaining at a specific location. That is, from the viewpoint of suppressing the change in pressure of the light source chamber 30, and furthermore, more reliably suppressing the attenuation of the light from the light source 32 or the oxidation of metal components in the light source chamber 30, the light source chamber 30 and the light source chamber-side exhaust duct 37 may be connected to each other by the exhaust pipes 36, rather than by the virtual exhaust pipe described above.

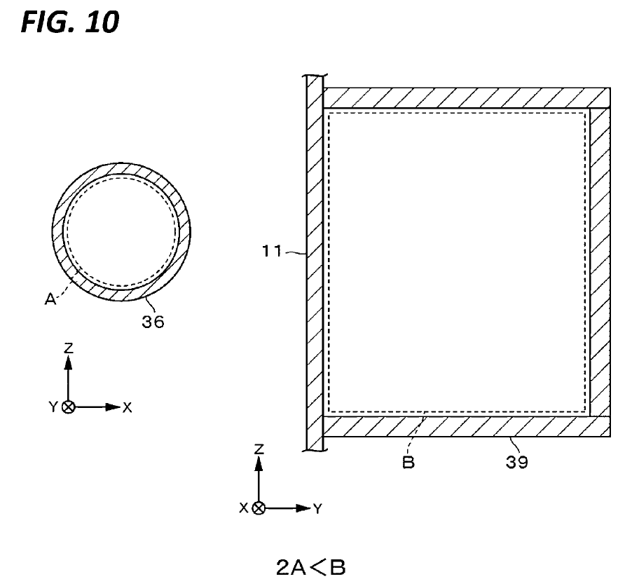

The configuration of the light source chamber-side exhaust duct 37 and the exhaust pipes 36 will be further described. FIG. 10 illustrates the cross section of each exhaust pipe 36 that is perpendicular to the flow path direction, and the cross section of the light source chamber-side exhaust duct 37 along the flow path direction. As described above, the cross-sectional area of the pipe passage of the exhaust pipe 36 is A. The cross-sectional area of the pipe passage of the light source chamber-side exhaust duct 37 will be defined as B. As described above, the flow path from the light source chamber 30 to the light source chamber-side exhaust duct 37 is configured to have the relatively greater gas pressure loss. More specifically, the pressure loss in the flow path from the light source chamber 30 toward the light source chamber-side exhaust duct 37 is set to be greater than the pressure loss in the light source chamber-side exhaust duct 37. Accordingly, the exhaust pipes 36 and the light source chamber-side exhaust duct 37 are each formed such that the cross-sectional area B of the light source chamber-side exhaust duct 37 is larger than the total cross-sectional area 2A of the two exhaust pipes 36.

Further, when the cross-sectional area of the processing chamber-side exhaust duct 69 in the flow path direction is defined as C, 2A<C. In a substrate processing apparatus 1B according to a second embodiment to be described herein later, the two exhaust pipes 36 are connected to the processing chamber-side exhaust duct 69 through the exhaust path formed by the exhaust path formation unit 6. However, as in the first embodiment, the gas pressure loss in the flow paths formed by the two exhaust pipes 36 is set to be greater than the gas pressure loss in the duct of the connection destination. With this configuration, the pressure change in the processing chamber-side exhaust duct 69 is suppressed from affecting the light source chamber 30.

Descriptions will return to the substrate processing apparatus 1 of the first embodiment. As described above with reference to FIG. 1, in the exhaust path for the processing chamber 70, the height D1 of the transverse exhaust path 65 and the length D2 of the vertical exhaust path 66 in the front-rear direction are set to be D1<D2. Thus, the transverse exhaust path 65 is narrow as compared to the vertical exhaust path 66, and the gas pressure loss in the transverse exhaust path 65 is high. Therefore, in the processing chamber 70 as well, the flow rate of the flowing gas and the pressure are suppressed from changing due to the change of pressure in the duct of the gas introduction destination (the processing chamber-side exhaust duct 69) as in the light source chamber 30.

The suppression of the change in the processing chamber 70 will be described in more detail referring back to FIG. 9. For example, it may be assumed that as the processing of the wafer W in the substrate processing apparatus 1a is stopped, the supply of the inert gas to the processing chamber 70 is stopped, and the pressure in the processing chamber-side exhaust duct 69 changes rapidly and significantly. However, in the flow path from the processing chamber 70 toward the processing chamber-side exhaust duct 69, the transverse exhaust path 65 is formed as a portion where the gas pressure loss is relatively high. Thus, in the processing chambers 70 of the substrate processing apparatuses 1b and 1c, the change in flow rate of the gas (e.g., air and inert gas) and the change in pressure are moderate and small. Therefore, the processing of the wafer W in the processing chambers 70 of the substrate processing apparatuses 1b and 1c is prevented from being affected by the change in internal pressure of the processing chamber-side exhaust duct 69.

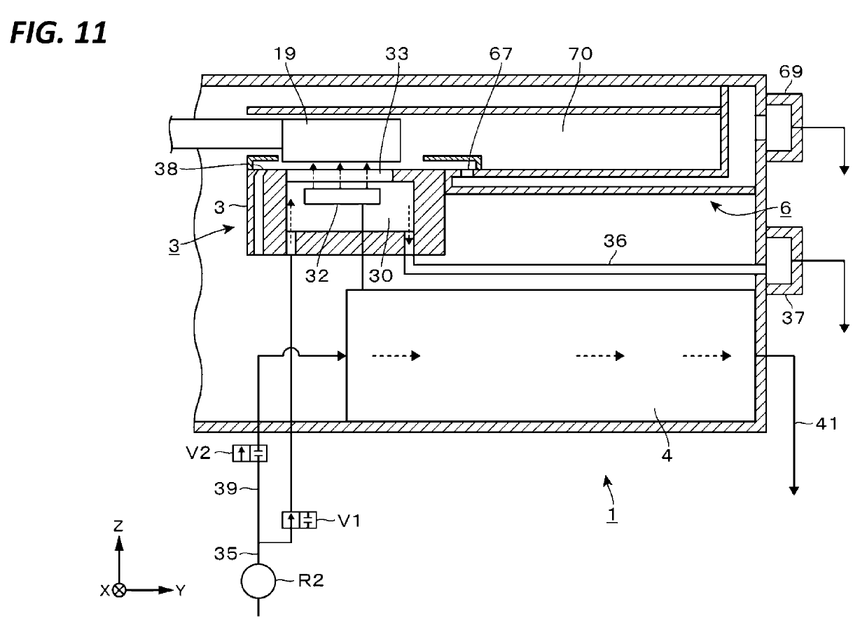

Next, the operation of the substrate processing apparatus 1 other than the operation performed for the processing of the wafer W will be described in more detail with reference to FIG. 11. As one of inspections performed on the substrate processing apparatus 1, the illuminance of the light irradiated from the light source 32 through the window 33 is measured. As illustrated in FIG. 11, the illuminance measurement is performed using an inspection jig 19 placed above the window 33 by an operator. In order to prevent damage to or contamination of the window 33, a gap is formed between the window 33 and the jig 19 with a predetermined height. Although not illustrated, members of the substrate processing apparatus 1 that may interfere with the placement of the jig 19 may be appropriately removed by the operator.

When the light irradiation for the illuminance measurement is performed, the valve V1 is opened to supply the inert gas to the light source chamber 30 as in the processing of the wafer W. However, when the inert gas is ejected from the gas ejection port 38 so that the flow of the inert gas is formed between the gas ejection port 38 and the exhaust port 67 as in the processing of the wafer W, the amount of O₃ gas on the window 33 may continuously fluctuate due to the flow of the inert gas, and consequently, the measured illuminance may become unstable. That is, when the inert gas is supplied to the processing chamber 70, the illuminance measurement may not be accurately measured.

Thus, when performing the illuminance measurement, it may be considered to close the valve V1 such that the inert gas is not ejected from the gas ejection port 38 (e. g., the inert gas is not supplied to the processing chamber 70). However, as described above with reference to FIG. 6, the plurality of substrate processing apparatuses 1 are connected to each other via the gas supply system. Thus, when the valve V1 is opened and closed during the illuminance measurement, the gas flow rate or the pressure in the processing chambers 70 and the light source chambers 30 of the other substrate processing apparatuses 1 that are not subjected to the illuminance measurement may change, causing disruption in the processing of the wafer W.

In order to prevent the influence on the other substrate processing apparatuses 1 that are not subjected to the illuminance measurement, the downstream end of the gas supply pipe 39, which has been connected to the housing 31 of the light irradiation unit 3, is connected to the power supply unit 4 such that the inert gas is supplied to the power supply unit 4 during the processing of the wafer W, in the example illustrated in FIG. 11. Accordingly, when performing the illuminance measurement, the operator reconnects the downstream end of the gas supply pipe 39 from the housing 31 to the power supply unit 4, in addition to installing the jig 19. After the reconnection by the operator, the valves V1 and V2 are opened such that the inert gas is supplied to each of the light source chamber 30 and the power supply unit 4, during the light irradiation for the illuminance measurement. The inert gas supplied to the power supply unit 4 is removed from the exhaust pipe 41 connected to the power supply unit 4. Further, the illuminance measured by the jig 19 is corrected based on a predetermined calculation formula to cancel the light attenuation caused by the O₃ gas present between the jig 19 and the window 33, so that the illuminance during the processing of the wafer W may be calculated.

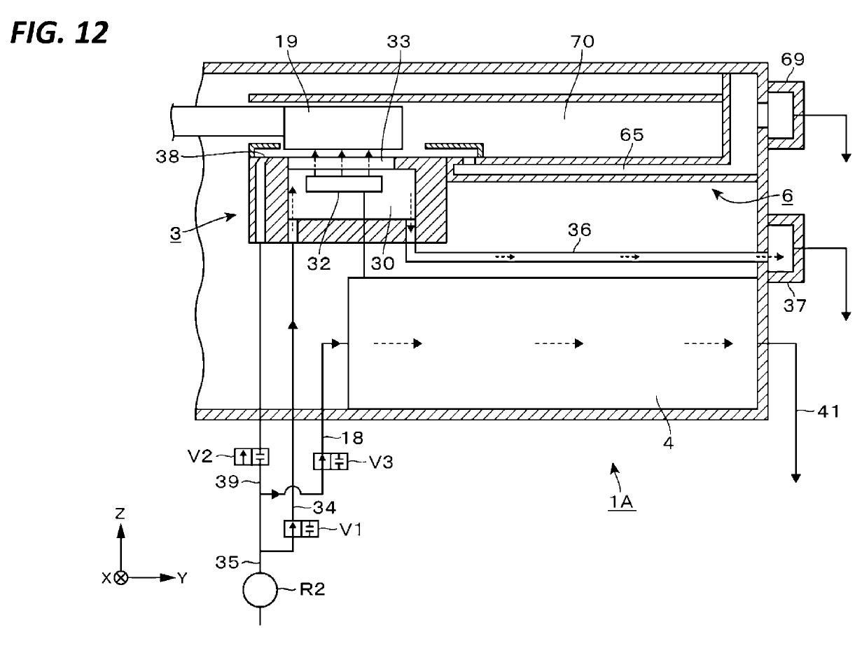

Meanwhile, FIG. 12 illustrates a longitudinal sectional side view of a substrate processing apparatus 1A, which is a modification of the substrate processing apparatus 1. The substrate processing apparatus 1A is different from the substrate processing apparatus 1, in that the substrate processing apparatus 1A does not require the reconnection of the gas supply pipe 39 by the operator when performing the illuminance measurement described above with reference to FIG. 11. The upstream end of a gas supply pipe 18 is connected to the upstream side of the location where the valve V2 is provided in the gas supply pipe 39. A valve V3 is interposed in the gas supply pipe 18, and the downstream end of the gas supply pipe 18 is connected to the power supply unit 4. During the processing of the wafer W, the valve V3 is closed, and the valve V1 is opened, so that the inert gas from the inert gas supply source 86 is supplied to the processing chamber 70. During the illuminance measurement, the valve V1 is closed, and the valve V3 is opened, so that the inert gas from the inert gas supply source 86 is supplied to the power supply unit 4.

As described above, the flow path formed by the gas supply pipe 18 is a bypass flow path that supplies the inert gas to a separate exhaust path (e.g., pipe passage of the exhaust pipe 41) from the exhaust path extending from the transverse exhaust path 65 to the duct 69 to make up the processing chamber-side exhaust unit, and the exhaust path extending from the exhaust pipes 36 to the duct 37 to make up the light source chamber-side exhaust unit, without allowing the inert gas to pass through the gas ejection port 38 making up the processing chamber-side gas supply unit. In the substrate processing apparatus 1A, by using the valves V1 and V3 that serve as switches, the inert gas supply destination may be switched between the processing chamber gas supply unit and the gas supply pipe 18, so that the operator's workload during the illuminance measurement may be reduced.

### <Second Embodiment>

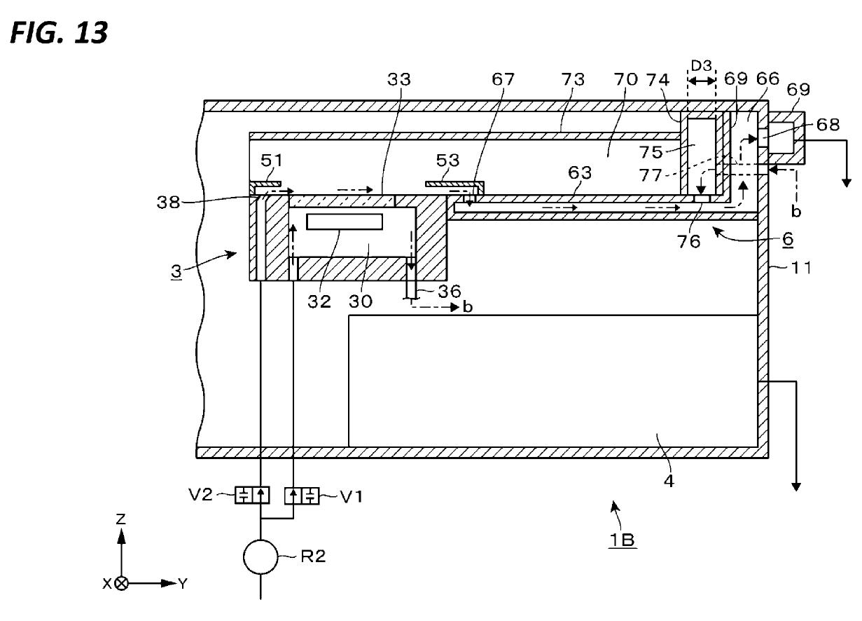

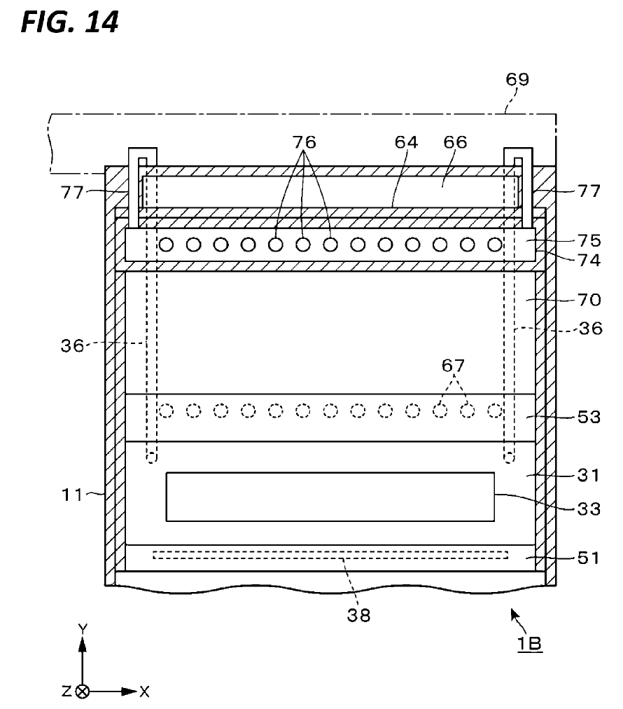

Next, a substrate processing apparatus 1B according to a second embodiment will be described, focusing on differences from the substrate processing apparatus 1, with reference to FIG. 13 that is a longitudinal sectional side view, and FIG. 14 that is a transverse plan view. In the substrate processing apparatus 1B, the light source chamber-side exhaust duct 37 is not provided, and the gas of the light source chamber 30 flows through the exhaust pipes 36, is introduced into the duct 69 via, for example, a buffer chamber 75 to be described herein later, and then, is exhausted from the duct 69. In FIG. 13, long and short dashed arrows indicate the gas flow.

On the rear end portion of the horizontal portion 63 of the exhaust path formation unit 6, a flow path formation member 74 is provided to be elongated in the left-right direction. The flow path formation member 74 has a substantially inverted U shape when viewed from the left-right direction, so that the region above the rear end portion of the horizontal portion 63 is enclosed by the flow path formation member 74 and the side wall of the housing 11 in the left-right direction. The region enclosed as described above is configured as the buffer chamber 75 partitioned from the surroundings. Further, in the horizontal portion 63, a plurality of through holes 76 is formed to be opened vertically. The through holes 76 are arranged in a row in the left-right direction while being spaced apart from each other. The buffer chamber 75 communicates with the transverse exhaust path 65 through the through holes 76, and the exhaust is performed from the buffer chamber 75 toward the transverse exhaust path 65.

The buffer chamber 75, which is a diffusion space for diffusing the gas, has a rectangular shape when viewed from each of the front-rear direction, the left-right direction, and the up-down direction, and the width of the buffer chamber 75 in the left-right direction is the same as the width of the transverse exhaust path 65 in the left-right direction. The length D3 of the buffer chamber 75 in the front-rear direction is greater than the height D1 of the transverse exhaust path 65 in the up-down direction (see, e.g., FIG. 1). Thus, the buffer chamber 75 is formed such that the gas pressure loss therein is smaller than that in the transverse exhaust path 65. Further, since the buffer chamber 75 is the space elongated in the left-right direction and having a strip shape in plan view, the width of the buffer chamber 75 in the left-right direction is greater than the length D3 thereof in the front-rear direction.

In the illustrated example, the downstream side of each exhaust pipe 36 is drawn backward relative to the buffer chamber 75. The gas flows from the downstream end of the exhaust pipe 36, and then, flows forward in flow paths 77 formed in the housing 11 to be introduced into the buffer chamber 75. Since the downstream ends of the flow paths 77 open into the left and right end portions of the buffer chamber 75, respectively, the gas is introduced into the buffer chamber 75 at the different locations in the left-right direction. The illustrated example represents the configuration in which the gas is introduced into the buffer chamber 75 from the rear side via the exhaust pipes 36 and the flow paths 77. However, without being limited thereto, the gas may be introduced into the buffer chamber 75 from the upper side or the front side.

With the configuration above, the gas in the light source chamber 30 is exhausted toward the transverse exhaust path 65 via the exhaust pipes 36, the flow paths 77 of the housing 11, the buffer chamber 75, and the through holes 76 in this order, and then, merges with the gas flowing from the processing chamber 70 in the transverse exhaust path 65. The merged gas between the gas from the light source chamber 30 and the gas from the processing chamber 70 is introduced into the duct 69 via the vertical exhaust path 66, and is exhausted. Accordingly, the buffer chamber 75 makes up a portion of the light source chamber-side exhaust unit.

As described in the first embodiment, since the height D1 of the transverse exhaust path 65 in the up-down direction is relatively small, the gas pressure loss in the transverse exhaust path 65 is relatively great. With the configuration in which the gas introduced from the exhaust pipes 36 passes through the transverse exhaust path 65 with the great gas pressure loss, and then, is introduced into the duct 69, it is possible to more reliably suppress the flow rate of the gas flowing in the light source chamber 30, and furthermore, the pressure of the light source chamber 30 from changing due to the change in pressure of the duct 69. Therefore, in the second embodiment, when the flow rate of the gas introduced into the duct 69 changes due to the occurrence of abnormality or the start or stop of the processing of the wafer W in one substrate processing apparatus, it is possible to suppress the change in pressure or the change in gas flow rate in the light source chambers 30 and the processing chambers 70 of the other substrate processing apparatuses, as in the first embodiment.

Further, the gas flowing from the exhaust pipes 36 is not introduced directly into the transverse exhaust path 65 configured to have the great pressure loss, but is introduced into the transverse exhaust path 65 after being introduced into the buffer chamber 75 configured to have a smaller pressure loss than the transverse exhaust path 65. Thus, the gas flowability may be prevented from being overly lowered in the flow path from the light source chamber 30 to the buffer chamber 75. Therefore, the O₃ gas generated in the light source chamber 30 may be quickly and reliably removed from the light source chamber 30.

The buffer chamber 75 is elongated in the left-right direction, and the light source chamber 30 is exhausted through the exhaust pipes 36 connected to the buffer chamber 75 at the different locations in the left-right direction via the flow paths 77. Since the buffer chamber 75 has the small gas pressure loss (e. g. , relatively high gas flowability) as described above, the exhaust is performed with high uniformity at the respective portions of the buffer chamber 75 in the left-right direction. Thus, as the buffer chamber 75 is exhausted, each of the left and right exhaust pipes 36 is exhausted with high uniformity, and as a result, the light source chamber 30 is highly uniformly exhausted from the locations spaced apart from each other in the left and right by the exhaust pipes 36. Therefore, the configuration of the present apparatus is also advantageous in that the O₃ gas generated in the light source chamber 30 may be rapidly and reliably removed.

Similarly to the buffer chamber 75, the vertical exhaust path 66 provided on the side of the rear end of the buffer chamber 75 is also elongated in the left-right direction and has the high gas flowability, and thus, may be regarded as a buffer chamber performing the same function as the buffer chamber 75. That is, by the operations of the buffer chamber 75 and the vertical exhaust path 66, the light source chamber 30 is exhausted with the high uniformity from the different locations in the left-right direction, and by the operation of the vertical exhaust path 66, the processing chamber 70 is exhausted with the high uniformity from the different locations in the left-right direction. In this way, in forming the buffer chamber 75 in front of the vertical exhaust path 66, which is a buffer chamber at the rear end side, to provide two side-by-side buffer chambers in the flow path, the buffer chamber 75 is disposed on the front side of the vertical exhaust path 66 to overlap with the transverse exhaust path 65 connecting the buffer chamber 75 and the vertical exhaust path 66, so that the space of the apparatus may be saved.

### <Third Embodiment>

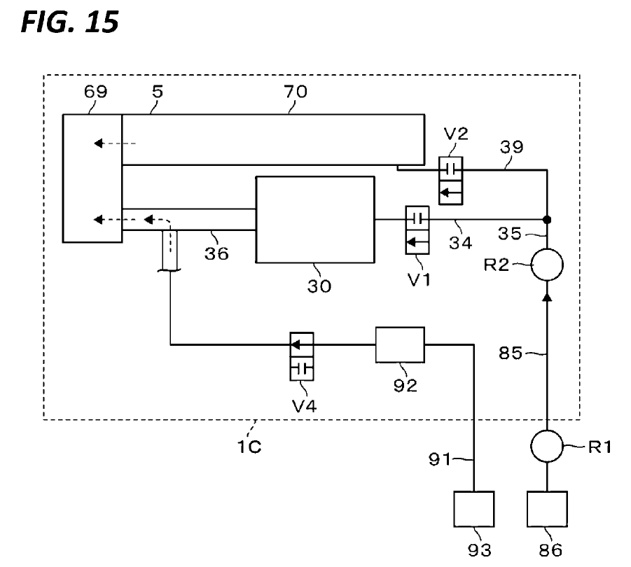

Next, a substrate processing apparatus 1C according to a third embodiment will be described, focusing on differences from the substrate processing apparatus 1B of the second embodiment, with reference to the schematic view of FIG. 15. In the substrate processing apparatus 1C as well, the light source chamber-side exhaust duct 37 is not provided, and the light source chamber 30 is exhausted by the duct 69 via the exhaust pipe 36. The downstream end of a gas supply pipe 91 is connected to the exhaust pipe 36. In the gas supply pipe 91, a valve V4 and a mass flow controller (MFC) 92 are interposed in this order toward the upstream side, and the upstream end of the gas supply pipe 91 is connected to a supply source 93 of air. The MFC 92 is a flow rate regulation unit that allows the air supplied from the supply source 93 to flow to the downstream side of the gas supply pipe 91 at a preset flow rate.

When the valve V1 in the opened state is closed due to the determined abnormality or the termination of the processing of the wafer W so that the supply of the inert gas to the light source chamber 30 is stopped, the valve V4 is opened simultaneously with the closing of the valve V1. As a result, the inert gas is not supplied to the duct 69 via the light source chamber 30, but the air is supplied to the duct 69 through the gas supply pipe 91. Accordingly, the change in flow rate of the gas supplied to the duct 69 is suppressed, so that the change in pressure inside the duct 69 is suppressed. Therefore, in the light source chambers 30 and the processing chambers 70 of the other substrate processing apparatuses 1 that share the duct 69 with the substrate processing apparatus 1C in which the valve V1 is closed, the change in gas flow rate and the change in pressure are suppressed.

### <Fourth Embodiment>

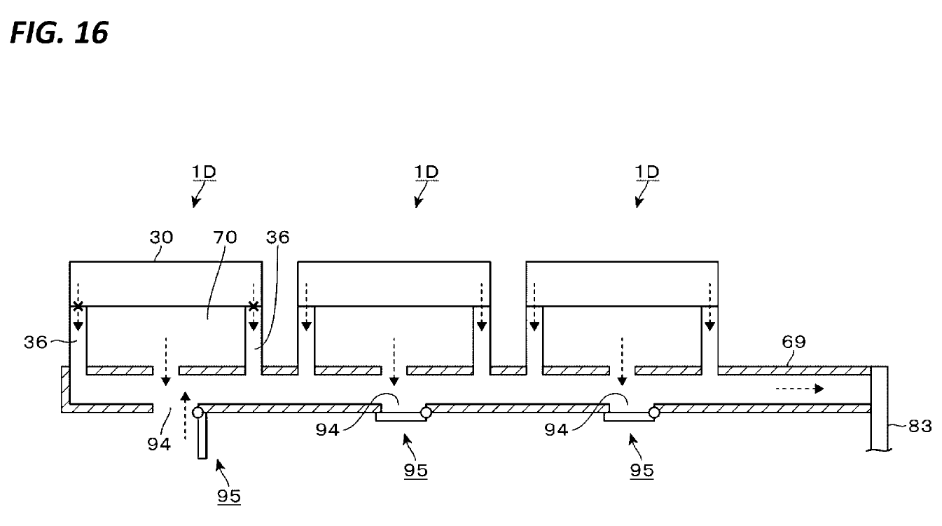

Next, a substrate processing apparatus 1D according to a fourth embodiment will be described, focusing on differences from the substrate processing apparatus 1B of the second embodiment, with reference to the schematic side view of FIG. 16. As in the examples described above, the duct 69 is shared among a plurality of, for example, three substrate processing apparatuses 1D. Meanwhile, unlike the examples described above, an opening 94 is formed in the vicinity of the location, to which the housing 11 of each substrate processing apparatus 1D is connected, in the duct 69. Specifically, for example, the opening 94 is formed at a position opposite to the location to which the housing 11 is connected, in the duct 69. Further, a damper 95 is provided in the duct 69 as an opening/closing mechanism that opens and closes each opening 94.

The damper 95 in the vicinity of the location to which the housing 11 is connected is the damper corresponding to the substrate processing apparatus 1D including the same housing 11, and operates in response to the state of the corresponding substrate processing apparatus 1D. In the normal state, each opening 94 is closed by the damper 95. When the valve V1 in the opened state is closed due to the determined abnormality or the termination of the processing of the wafer W in one substrate processing apparatus 1D so that the supply of the inert gas to the light source chamber 30 is stopped, the damper 95 corresponding to the one substrate processing apparatus 1D operates simultaneously with the closing of the valve V1, thereby opening the opening 94.

Accordingly, in the vicinity of the location to which the one substrate processing apparatus 1D is connected in the duct 69, the inert gas is not supplied via the light source chamber 30, but the air is introduced through the opening 94. As a result, since the change in internal pressure of the duct 69 is suppressed, it is possible to suppress the change in gas flow rate and the change in pressure in the light source chambers 30 and the processing chambers 70 of the other substrate processing apparatuses 1D sharing the duct 69 with the one substrate processing apparatus 1D.

The positions where the opening 94 and the damper 95 are provided are arbitrary, and further, the present disclosure is not limited to the configuration in which a single damper 95 corresponds to a single substrate processing apparatus 1D. For example, the damper 95 and the opening 94 may be provided between two adjacent substrate processing apparatuses 1D in the longitudinal direction of the duct 69. Accordingly, in the case where three substrate processing apparatuses 1D share the duct 69 as in the example of FIG. 16, two dampers 95 and two openings 94 may be provided while being spaced apart from each other in the left-right direction, respectively. Then, the left damper 95 may operate in response to the closing of the valve V1 of the left and central substrate processing apparatuses 1D, and the right damper 95 may operate in response to the closing of the valve V1 of the right and central substrate processing apparatuses 1D.

The duct 69 may be connected to the housing 11 of the substrate processing apparatus 1D by a flow path formation member, and the vertical exhaust path 66 formed by the exhaust path formation unit 6 of the substrate processing apparatus 1D and the flow path in the duct 69 may be connected to each other through the flow path formed in the flow path formation member. In this case, the damper 95 may be provided in the flow path formation member. Therefore, the installation position of the damper 95 is not limited to the duct 69.

### <Other Configuration of Substrate Holding Unit>

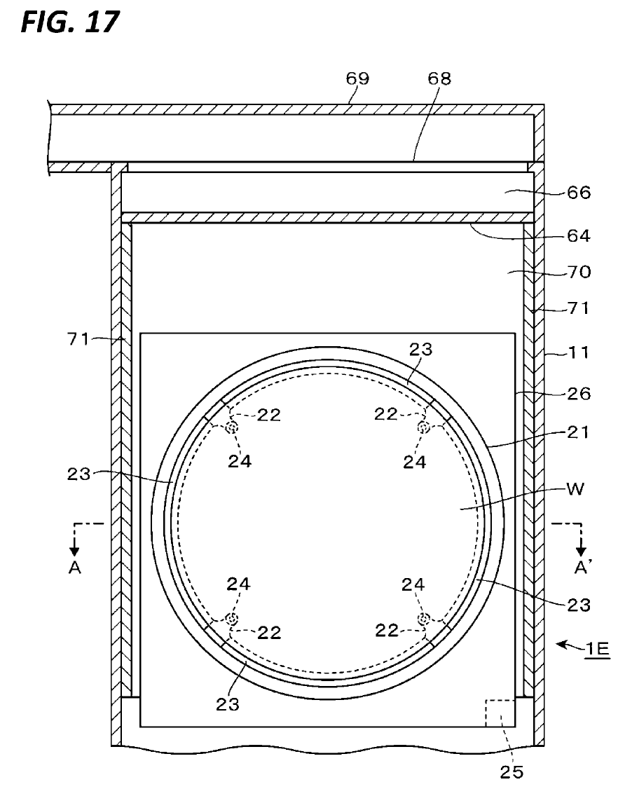

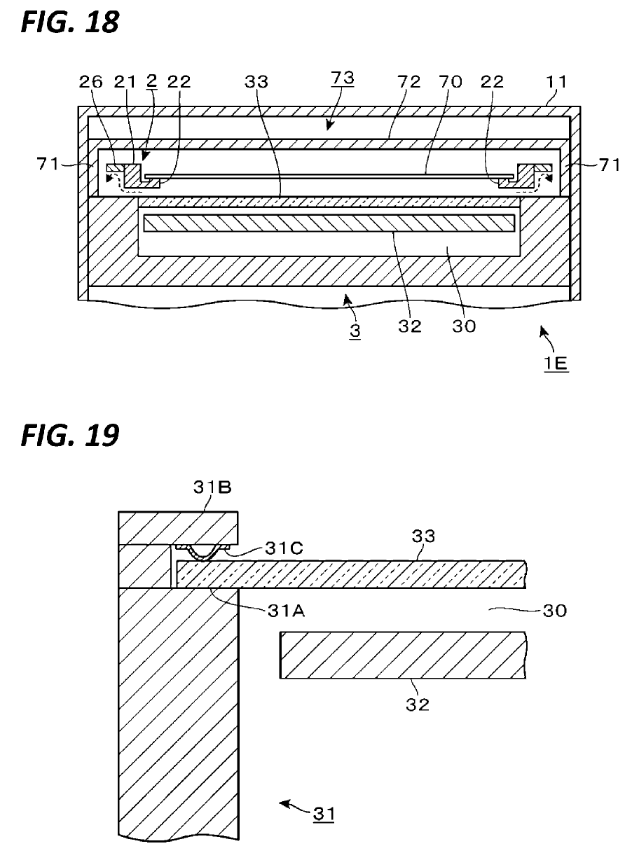

A substrate processing apparatus 1E, which is another modification of the substrate processing apparatus 1 of the first embodiment, will be described, focusing on differences from the substrate processing apparatus 1, with reference to the plan view of FIG. 17 and the longitudinal sectional front view of FIG. 18. FIG. 18 is a sectional view when viewed from the direction of the arrow A-A′ in FIG. 17. In the substrate processing apparatus 1E, a protrusion 26 is formed at the upper end of the outer peripheral side surface of a substrate holding unit 21 that is an annular member. The protrusion 26 is a plate-like member that protrudes horizontally toward the outside of the substrate holding unit 21 from the entire circumference of the substrate holding unit 21. Accordingly, the protrusion 26 protrudes to the left side and the right side from the entire left side surface of the substrate holding unit 21 and the entire right side surface of the substrate holding portion 21, respectively. In plan view, the outer shape of the protrusion 26 is rectangular, and the left and right sides of the protrusion 26 extend in the moving direction of the movement member 20 (e. g., the front-rear direction). The movement mechanism 25 is connected to the portion of the protrusion 26 that protrudes forward from the substrate holding unit 21, to move the substrate holding unit 21 forward and backward.

The left and right support units 71 of the cavity formation member 73 that forms the processing space 70 each also extend in the front-rear direction. When the light irradiation is performed on the wafer W, the protrusion 26 enters the processing space 70 together with the substrate holding unit 21, and the left end and the right end of the protrusion 26 approach the left support unit 71 and the right support unit 71, respectively, as illustrated in FIGS. 17 and 18.

Similarly to the airflow direction regulation plate 53 described above, the protrusion 26 functions to regulate the flow of the inert gas, thereby preventing the removal of the resist film on the front surface of the wafer W. Specifically, since the substrate holding unit 21 moves forward and rearward during the processing of the wafer W, the substrate holding unit 21 and the wafer W may not be positioned above the exhaust port 67. In that state, in a case where the protrusion 26 and the airflow direction regulation plate 53 are not provided, the inert gas ejected from the gas ejection port 38 may be supplied above the wafer W together with the O₃ gas generated by the light irradiation since the exhaust port 67 sucks the atmosphere of the upper region of the processing space 70, as described above regarding the airflow direction regulation plate 53.

However, as described above, the airflow direction regulation plate 53 (illustration thereof is omitted in FIGS. 17 and 18) is provided, so that the suction of the atmosphere in the upper region of the processing space 70 is suppressed. Further, with the configuration in which the protrusion 26 approaches the cavity formation member 73, the inert gas ejected from the gas ejection port 38 is prevented from flowing around onto the front surface of the wafer W from the left and right sides of the substrate holding unit 21, as indicated by dashed arrows in FIG. 18. Therefore, in the substrate processing apparatus 1E, the removal of the resist film is prevented as described above.

### <Configuration of Light Irradiation Unit>

The light irradiation unit 3 may be configured such that either one of the peripheral edge of the window 33 and a member making up a window frame of the housing 31 is pressed against the other by a plate spring, which is an elastic member, to seal the light source chamber 30 (e.g., to become a sealed space). As illustrated in FIG. 19 for an example of the specific configuration, on the upper surface of the side wall of the housing 31 that forms the window frame, the inner peripheral edge side is formed to be lower than the outer peripheral edge side, thereby forming a stepped portion 31A, and the peripheral edge of the window 33 is supported on the stepped portion 31A. An annular member 31B is provided by being stacked on the outer peripheral edge side of the side wall, and is formed along the peripheral edge of the window 33, and the peripheral edge of the window 33 is pressed downward toward the stepped portion 31A by a plate spring 31C interposed between the annular member 31B and the window 33, so that the light source chamber 30 is sealed.

The plate spring 31C is provided for each side of the rectangular window 33, and extends along the corresponding side to press the linear region along each side of the window 33. By using the plate spring, it is possible to suppress the application of excessive force, which is likely to damage the window 33, to the window 33.

In the configuration in which the light source chamber 30 is sealed by the plate spring as described above, it is concerned that the inert gas supplied to the light source chamber 30 may slightly leak into the processing chamber 70 outside the housing 31 through the sealing surface of the window 33 (the contact surface of the window 33 pressed toward the window frame by the plate spring; in the example of FIG. 19, the contact surface of the window 33 with the stepped portion 31A). However, even when the leakage occurs, the flow rate of the inert gas supplied from the gas ejection port 38 to the processing chamber 70 may be adjusted, so that it is possible to maintain the environment of the processing chamber 70 that has the appropriate oxygen concentration to perform the processing of the wafer W.

Meanwhile, the pressure of the light source chamber 30 (referred to as the internal pressure value) detected by the pressure sensor 15 of the light source chamber 30 changes in response to a fluctuation in flow rate of the inert gas supplied to the light source chamber 30. The amount of inert gas leaking into the processing chamber 70 through the sealing surface of the window 33 (referred to as the leakage amount of the inert gas) changes in accordance with the internal pressure value.

Thus, correlation data are acquired in advance between the internal pressure value and the appropriate flow rate of the inert gas to be supplied from the gas ejection port 38 into the processing chamber 70. Then, for example, a flow rate adjustment mechanism, such as a mass flow controller, is provided in the gas supply pipe 39 for supplying the inert gas to the gas ejection port 38. The operation of the flow rate adjustment mechanism is controlled by a control signal from the control device 100, and the flow rate of the inert gas supplied to the processing chamber 70 may be changed in accordance with the control signal.

The control device 100 monitors the internal pressure value, and controls the operation of the flow rate adjustment mechanism based on the internal pressure value and the above-described correlation data, such that the flow rate of the inert gas supplied to the processing chamber 70 becomes the flow rate corresponding to the internal pressure value. That is, the flow rate of the inert gas supplied to the processing chamber 70 is automatically adjusted to follow the state of the leakage from the light source chamber 30 through the sealing surface. In this way, by performing the flow rate adjustment, the oxygen concentration in the processing chamber 70 may be stabilized.

For example, it may be assumed that data has been acquired, representing that the appropriate range of the flow rate of the inert gas supplied to the processing chamber 70 is 5 L/min to 25 L/min when the gas leakage from the light source chamber 30 is at its maximum, and the appropriate range of the flow rate of the inert gas supplied to the processing chamber 70 is 10 L/min to 30 L/min when the gas leakage from the light source chamber 30 is at its minimum. In this case, the reference range of the flow rate of the inert gas supplied to the processing chamber 70 may be 10 L/min to 25 L/min. That is, the correlation data may be set such that when the acquired internal pressure value is relatively great or relatively small within the allowable range, the supply flow rate is out of the reference range.

In each embodiment, the substrate to be processed is not limited to a wafer, and may be, for example, a substrate for manufacturing a flat panel display or a mask substrate for manufacturing an exposure mask. Therefore, a substrate with a rectangular shape may be processed.

The present disclosure may stably perform the processing by light irradiation onto the back surface of a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A substrate processing apparatus comprising:
a substrate holder configured to hold a substrate in a processing chamber;
a light irradiation unit including a light source, a housing that accommodates the light source and forms a light source chamber partitioned from the processing chamber, and a window that forms a portion of the housing and transmits light emitted from the light source to supply the light to a back surface of the substrate in the processing chamber, thereby performing a processing;
a processing chamber-side gas supply configured to supply an inert gas to the processing chamber;
a processing chamber-side exhaust configured to exhaust the inert gas from the processing chamber;
a light source chamber-side gas supply configured to supply the inert gas to the light source chamber; and
a light source chamber-side exhaust configured to exhaust the inert gas from the light source chamber.

2. The substrate processing apparatus according to claim 1, wherein the light source chamber-side exhaust includes a plurality of exhaust paths that branches in a left-right direction from the light source chamber.

3. The substrate processing apparatus according to claim 1, further comprising:
a bypass flow path that supplies the inert gas supplied from an inert gas supply source to an exhaust path formed separately from the processing chamber-side exhaust and the light source chamber-side exhaust, without allowing the inert gas to flow through the processing chamber-side gas supply; and
a switch that switches a supply destination of the inert gas supplied from the inert gas supply source between the processing chamber-side gas supply and the bypass flow path.

4. The substrate processing apparatus according to claim 1, wherein the processing chamber-side exhaust includes a processing chamber-side exhaust duct connected to an exhaust source,
the light source chamber-side exhaust includes a light source chamber-side exhaust duct connected to an exhaust source, and
the processing chamber-side exhaust duct and the light source chamber-side exhaust duct are provided separately from each other.

5. The substrate processing apparatus according to claim 1, wherein the light source chamber-side exhaust includes a buffer chamber of which downstream side is connected to the processing chamber-side exhaust.

6. The substrate processing apparatus according to claim 5, wherein the light source chamber-side exhaust includes a plurality of exhaust paths that branches in a left-right direction from the light irradiator,
the buffer chamber is a space having a greater length in a left-right direction than a length thereof in a front-rear direction and partitioned from surroundings, and
a gas is introduced from the plurality of exhaust paths to different locations of the buffer chamber in the left-right direction.

7. The substrate processing apparatus according to claim 1, wherein the processing chamber-side gas supply includes an ejection port formed at one side with respect to the window and opened obliquely toward an opposite side to eject the inert gas,
the processing chamber-side exhaust includes an exhaust port formed at the opposite side with respect to the window and exhausting the inert gas ejected from the ejection port and passing over a front surface of the window,
a first regulator is provided to cover the ejection port with a gap to regulate a flow of the inert gas, and
a second regulator is provided to cover the exhaust port with a gap to regulate the flow of the inert gas.

8. A substrate processing method comprising:
holding the substrate in a processing chamber by a substrate holder;
irradiating light from a light irradiation unit including a light source, a housing that accommodates the light source and forms a light source chamber partitioned from the processing chamber, and a window that forms a portion of the housing and transmits the light emitted from the light source to supply the light to a back surface of the substrate in the processing chamber, thereby performing a processing;
supplying an inert gas to the processing chamber by a processing chamber-side gas supply;
exhausting the inert gas from the processing chamber by a processing chamber-side exhaust;
supplying an inert gas to the light source chamber by a light source chamber-side gas supply; and
exhausting the inert gas from the light source chamber by a light source chamber-side exhaust.
